(19) United States
(12) Patent Application Publication
(10) Pub. No.: US 2024/0071494 A1
(43) Pub. Date: Feb. 29, 2024

(54) AND TYPE FLASH MEMORY, PROGRAMMING METHOD AND ERASING METHOD

(71) Applicant: Winbond Electronics Corp., Taichung City (TW)

(72) Inventor: Riichiro Shirota, Kanagawa (JP)

(73) Assignee: Winbond Electronics Corp., Taichung City (TW)

(21) Appl. No.: 18/454,051

(22) Filed: Aug. 22, 2023

(30) Foreign Application Priority Data
Aug. 25, 2022 (JP) 2022-133799

(51) Int. Cl. G11C 16/04; G11C 16/10; G11C 16/16; H10B 43/35

(52) U.S. Cl. CPC G11C 16/0466; G11C 16/10; G11C 16/16; H10B 43/35

(57) ABSTRACT

An AND type flash memory is provided. The AND type flash memory includes a plurality of memory cells connected in parallel between a source line and a bit line. The memory cell includes a charge accumulation layer including a SiN layer serving as a gate insulating film. In case of programming, electrons tunneled from a channel FN are accumulated in the charge accumulation layer of the memory cell. In case of erasing, the electrons accumulated in the charge accumulation layer of the memory cell are released to the channel.

### CROSS-REFERENCE TO RELATED APPLICATION

This application claims the priority benefit of Japan application serial no. 2022-133799, filed on Aug. 25, 2022. The entirety of the above-mentioned patent application is hereby incorporated by reference herein and made a part of this specification.

### BACKGROUND

### Technical Field

The invention relates to a flash memory constructed by an AND type memory cell array.

### Description of Related Art

(A) of FIG. 1 is an equivalent circuit of an existing NOR type flash memory. A source/drain of each memory cell is connected between a bit line BL and a source line SL (virtual grounding), and a gate thereof is connected to a word line WL, so as to implement reading or programming of each memory cell. In the NOR type flash memory, since it is unable to scale a gate length of the memory cell to be less than 100 nm, scaling of the memory cell is limited. Moreover, in the case that the gate length cannot be scaled, a channel width of a read current that should be obtained during a reading operation cannot be scaled. Therefore, the size of the memory cell has roughly reached its limit.

(B) of FIG. 1 is an equivalent circuit of an AND type flash memory (non-patent literature 1). In the AND flash memory, a plurality of memory cells are connected in parallel between a local bit line LBL and a local source line LSL, and each gate of the memory cell is connected to a word line WL. The local bit line LBL is connected to the bit line BL via a selection transistor of a bit line side, and the local source line LSL is connected to the source line SL via a selection transistor of a source line side. When selecting a memory cell, the selection transistor of the bit line side is turned on through a selection control line SG1, and the selection transistor of the source line side is turned on through a selection control line SG2.
[Non-patent literature 1] “A 0.24-um2 Cell Process with 0.18 um Width Isolation and 3-D Interpoly Dielectric Films for 1-Gb Flash Memories”, Takashi Kobayashi et al., 1997 IEDM, p 275-278.

In the existing AND type flash memory, during a programming operation, since the local source line LSL is floating, a problem of programming punch-through does not occur. However, in programming, it is necessary to implant hot electrons generated by channel current between the source and the drain into a floating gate, and in order to eliminate electrons from the floating gate FG towards the local bit line LBL for erasing, it is necessary to increase an overlapping area between the drain and the floating gate FG. Therefore, there is a problem that it is difficult to miniaturize a cell size.

### SUMMARY

The invention is directed to an AND type flash memory, seeking miniaturization of a memory cell size to achieve high integration.

The invention provides an AND type flash memory including a memory cell array, the memory cell array includes a plurality of memory cells electrically connected in parallel between a source line and a bit line. A plurality of parallel and elongated diffusion regions are formed in the memory cell array, and the plurality of memory cells connected in parallel respectively include a gate and a charge accumulation layer, and the gate is disposed between the diffusion regions opposite to each other, the charge accumulation layer serves as a gate insulating film, and is capable of storing charges, and the charge accumulation layer includes at least three or more insulating layers.

The invention provides a programming method, adapted to an AND type flash memory, wherein the AND type flash memory includes a memory cell array, the memory cell array includes a plurality of memory cells electrically connected in parallel between a source line and a bit line. A plurality of parallel and elongated diffusion regions are formed in the memory cell array, and the plurality of memory cells connected in parallel respectively include a gate and a charge accumulation layer, and the gate is disposed between the diffusion regions opposite to each other, the charge accumulation layer serves as a gate insulating film, and includes at least three or more insulating layers, and a program voltage is applied to the gate of a selected memory cell, and a reference voltage is applied to a channel, thereby accumulating charges tunneled from the channel in the charge accumulation layer.

The invention provides an erasing method, adapted to an AND type flash memory, wherein the AND type flash memory includes a memory cell array, the memory cell array includes a plurality of memory cells electrically connected in parallel between a source line and a bit line. A plurality of parallel and elongated diffusion regions are formed in the memory cell array, and the plurality of memory cells connected in parallel respectively include a gate and a charge accumulation layer, and the gate is disposed between the diffusion regions opposite to each other, and the charge accumulation layer serves as a gate insulating film, and includes at least three or more insulating layers, and a reference voltage is applied to the gate of a selected memory cell, and an erase voltage is applied to a well including a channel, and charges accumulated in the charge accumulation layer are released to the channel through tunneling. In a certain form, a block including a plurality of memory cells connected in parallel is selected, and the plurality of memory cells in the selected block are erased all at once.

According to the invention, in the AND type memory cell array, since the memory cell has a charge accumulation layer including at least three or more insulating layers and capable of storing charges, it is possible to realize miniaturization of the memory cell array and simplification of the manufacturing process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

(A) of FIG. 1 is an equivalent circuit of an existing NOR type flash memory.

(B) of FIG. 1 is an equivalent circuit of an AND type flash memory.

FIG. 2 is a plan view schematically showing a structure of an AND type memory cell array according to an embodiment of the invention.

FIG. 2A is an equivalent circuit of an AND type memory cell array according to an embodiment of the invention.

FIG. 3, FIG. 4, FIG. 5 and FIG. 6 are respectively cross-sectional views of FIG. 2 along a line B-B, a line A-A, a line D-D and a line E-E.

FIG. 7 is a plan view showing another example of contacts of the memory cell array shown in FIG. 2.

FIG. 8 is a diagram showing an equivalent circuit of an AND type flash memory according to an embodiment of the invention.

FIG. 9 is a cross-sectional view showing a manufacturing process of the AND type flash memory according to an embodiment of the invention.

FIG. 10 to FIG. 17 are cross-sectional views and plan views showing the manufacturing process of the AND type flash memory according to an embodiment of the invention.

FIG. 18 is a cross-sectional view showing a manufacturing process of the AND type flash memory according to an embodiment of the invention.

FIG. 19 is a block diagram showing an electrical structure of an AND type flash memory according to an embodiment of the invention.

### DESCRIPTION OF THE EMBODIMENTS

The invention relates to a metal-oxide-nitride-oxide-semiconductor (MONOS) type or silicon-oxide-nitride-oxide-silicon (SONOS) type AND-type flash memory constructed by a memory cell array, which has a following structure: trapping charges from a channel to a silicon nitride (SiN) layer, or releasing charges from the SiN layer to the channel via Fowler-Nordheim (FN) tunneling. In this way, the problem of punch-through from a drain to a source of a memory cell is eliminated, and an overlapping area from the drain to a gate is suppressed to the minimum, so that the miniaturization of the memory cell and the simplification of the manufacturing process may be achieved.

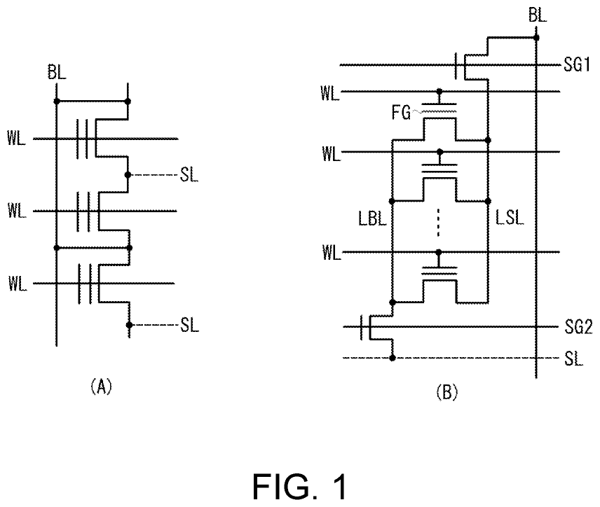

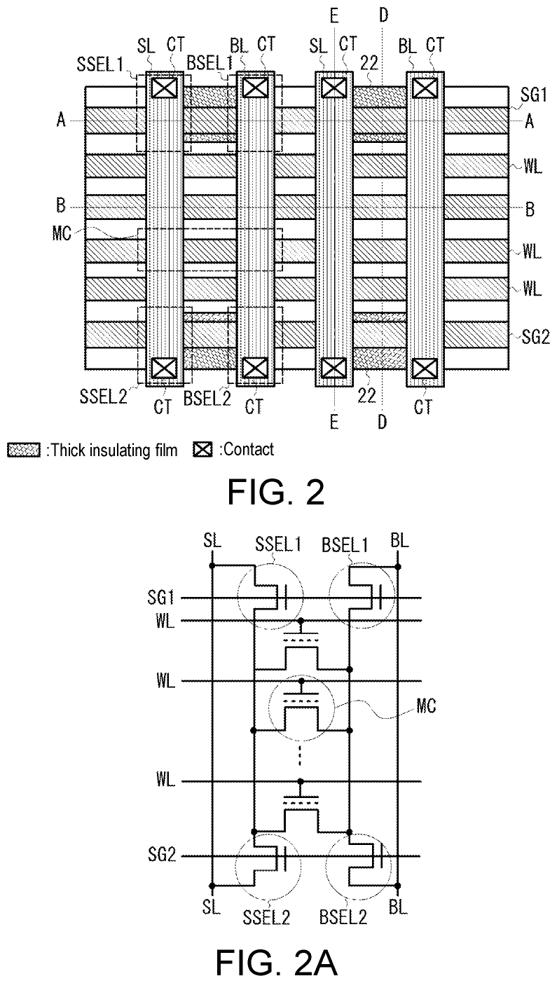

As shown in FIG. 2 and FIG. 2A, bit lines BL and source lines SL alternately extend along a column direction, and word lines WL, a selection control line SG1, and a selection control line SG2 in a lower layer extend along a row direction. The source line SL is connected to a selection transistor SSEL1 of a source line side and a selection transistor SSEL2 of the source line side through contacts CT, and the bit line BL is connected to a selection transistor BSEL1 of a bit line side and a selection transistor BSEL2 of the bit line side through the contacts CT.

A plurality of memory cells MC electrically connected to the source line SL and the bit line BT in parallel are formed between the selection transistor SSEL1 of the source line side, the selection transistor BSEL1 of the bit line side and the selection transistor SSEL2 of the source line side, the selection transistor BSEL2 of the bit line side, and the memory cells connected in parallel form a block.

Gates of the selection transistor SSEL1 of the source line side and the selection transistor BSEL1 of the bit line side in the row direction are commonly connected to the corresponding selection control line SG1, and gates of the selection transistor SSEL2 of the source line side and the selection transistor BSEL2 of the bit line side in the row direction are commonly connected to the corresponding selection control line SG2. Moreover, gates of the memory cells in the row direction are connected to the corresponding word line WL.

A rectangular area represented by dotted lines in FIG. 2 represents one memory cell MC, and other rectangular areas represent the selection transistor SSEL1 of the source line side, the selection transistor SSEL2 of the source line side, and the selection transistor BSEL1 of the bit line side and the selection transistor BSEL2 of the bit line side.

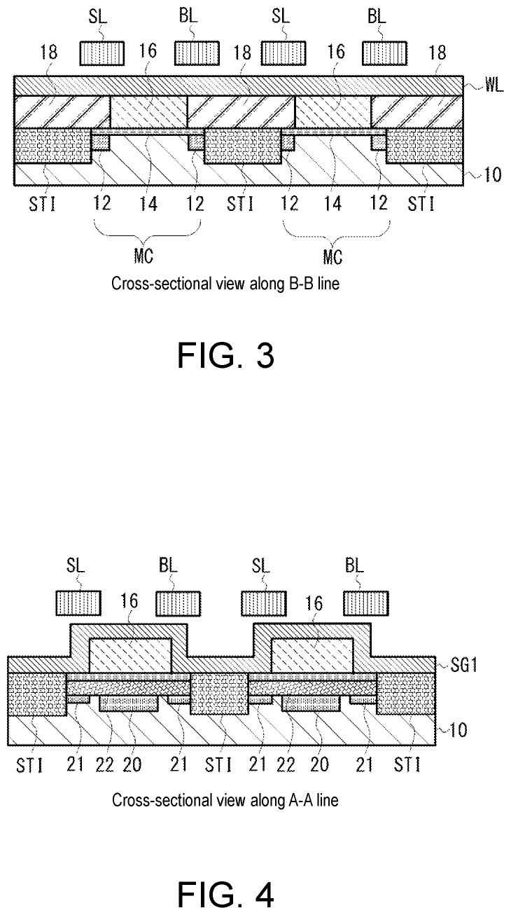

FIG. 3 shows a cross-section of a memory cell. An N well is formed in a P-type silicon substrate, and a P well 10 is formed in the N well. An N-type diffusion region 12 extending parallel to the source line SL and the bit line BL is formed on a surface of the P well 10. The diffusion region 12 of the source line side and the diffusion region 12 of the bit line side provide a source/drain of the memory cell. A charge accumulation layer 14 including at least three or more insulating layers is formed as a gate insulating film on the surface of the P well 10. The charge accumulation layer 14 has, for example, an ONO structure (SiO₂/SiN/SiO₂), and SiN stores electrons tunneled from a channel FN. A gate 16 made of conductive polysilicon, etc., is formed on the charge accumulation layer 14, and the gate 16 is electrically connected to the word line WL.

One memory cell MC is composed of a diffusion region 12, a charge accumulation layer 14, a gate 16, and a WL wiring electrically connected to the gate 16. In order to electrically separate adjacent memory cells along the row direction, shallow trench isolations (STI) extending along the column direction are formed between the diffusion regions 12. Moreover, the shallow trench isolations STI also simultaneously separate the charge accumulation layer 14 of the adjacent memory cells along the row direction. However, as shown in FIG. 5, the charge accumulation layer 14 extends in the column direction and is shared by the memory cells adjacent in the column direction. The shallow trench isolation STI is, for example, a silicon oxide region. Furthermore, an interlayer insulating film 18 is formed between the gates 16.

FIG. 4 shows cross-sections of the selection transistor SSEL1 of the source line side and the selection transistor BSEL1 of the bit line side. The electrically connected SG1 wiring serving as the selection control line is configured on the gate 16, and a thick insulating film 22 is formed directly under the gates 16 of the selection transistor SSEL1 and the selection transistor BSEL1 in addition to the charge accumulation layer 14. The thick insulating film 22 is, for example, a silicon oxide film. Moreover, a P+ high impurity diffusion region 20 is formed directly under the thick insulating film 22. The diffusion region 20 is formed to adjust a threshold Vt of the selection transistor. Furthermore, a P+ high impurity diffusion region 21 is formed under the source line SL and the bit line BL and directly under the thick insulating film 22. The diffusion region 21 increases a withstand voltage between the N-type diffusion regions connected to the contacts CT of the source line SL/bit line BL, and prevents conduction of the diffusion region 12 of the source line side and the diffusion region 12 of the bit line side when the selection transistor SSEL1 and the selection transistor BSEL1 are turned on.

FIG. 5 shows a cross section of a memory cell. The gate 16 of the memory cell is formed on the silicon surface of the P well 10 via the charge accumulation layer 14, and the gate 16 is electrically connected to the corresponding word line WL.

FIG. 6 shows a cross section of a selection transistor. The gate 16 of the selection transistor SSEL1 is connected to the selection control line SG1. Moreover, one of the N-type diffusion regions 13 of the selection transistor SSEL1 is electrically connected to the diffusion region 12 of the memory cell, and the other N-type diffusion region 13 is electrically connected to the source line SL through the contact CT. Namely, the diffusion region 12 extending along the column direction and used for forming the source/drain of the memory cell is not formed in the region where the selection transistor SSEL1 is formed. As described above, in the channel of the selection transistor, the P+ high impurity diffusion region 20 forms a channel blocking boron-doped region (in the case of a P-type silicon substrate) or an As-doped region (in the case of an N-type silicon substrate). Thus, the threshold voltage (Vt) of the selection transistor may be adjusted.

As the gate insulating film of the selection transistor, a thick insulating film 22 is added to the charge accumulation layer 14, which prevents charge accumulation in the charge accumulation layer of the selection transistor to cause variation of the threshold Vt of the selection transistor even if a high voltage is applied to the gate of the selection transistor. However, the thick insulating film 22 is not essential, which may be omitted as long as a high voltage such as charges accumulated in the charge accumulation layer 14 is not applied to the gate. Also, the selection transistor SSEL2 of the source line side and the selection transistor BSEL2 of the bit line side are constructed in the same manner.

An orientation of the selection transistor SSEL1 is 90 degrees different from an orientation of the memory cell MC, i.e., the selection transistor SSEL1 selectively connects/disconnects the diffusion region 12 of the source line side of the memory cell MC to the source line SL. The selection transistor SSEL1 is turned on when the selection control line SG1 is higher than the threshold Vt of the selection transistor SSEL1, and electrically connects the diffusion region 12 of the memory cell to the source line SL. The selection transistor SSEL2 is also configured in the same manner as the selection transistor SSEL1, and the selection transistor BSEL1 of the bit line side and the selection transistor BSEL2 of the bit line side that are not shown are also configured in the same manner.

In the embodiment, by adopting the AND type cell structure, different to the existing AND type flash memory, the selection control line SG1, the selection control line SG2 and the word line WL may be formed simultaneously. Moreover, as shown in FIG. 3, the charge accumulation layer 14 is separated between the memory cells, thereby avoiding diffusion of charges from one memory cell to an adjacent memory cell, so as to improve data retention.

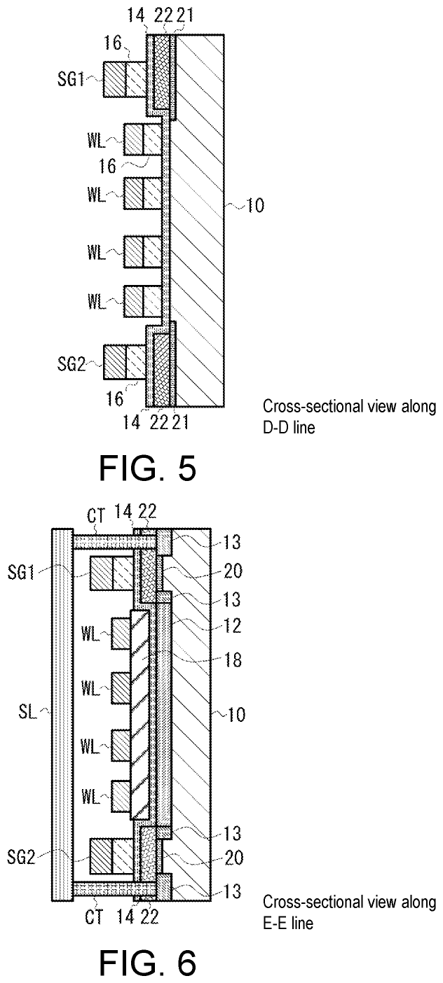

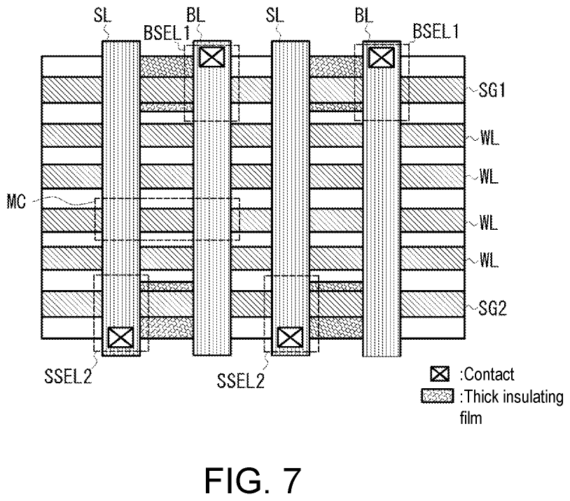

FIG. 7 shows a modified example of the AND type cell array structure of the embodiment. A contact area between the source line SL and the bit line BL is serrated, and the layout corresponds to the equivalent circuit shown in (B) of FIG. 1. By using the layout shown in FIG. 7, it is possible to reduce a situation that a cell current flowing from the bit line BL to the source line SL in the reading operation depends on a position of the bit line WL.

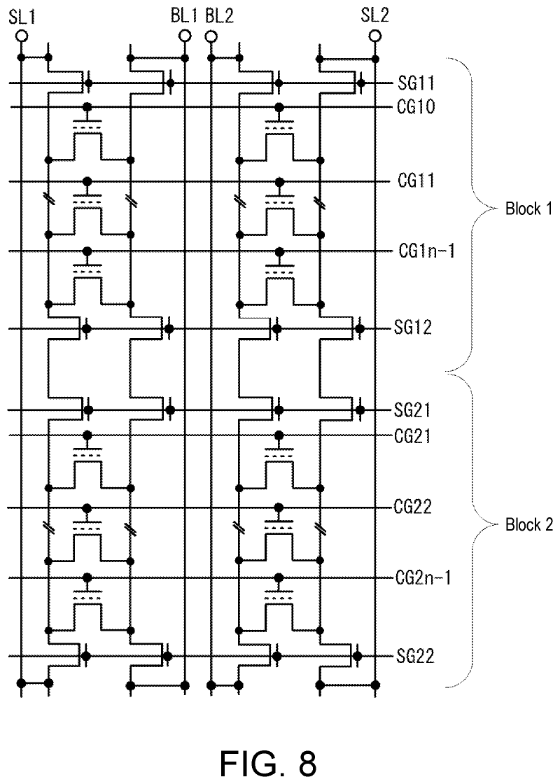

Referring to FIG. 8 and Table 1, the operation of the AND type flash memory of the embodiment is described below. The operation of the embodiment is a unique operation utilizing electron tunneling between the SiN layer and the channel. FIG. 8 illustrates an equivalent circuit of a memory cell array including two blocks, for example, in a block 1, the n memory cells connected in parallel are connected in parallel between the selection transistor of the bit line side and the selection transistor of the source line side, the selection control line SG11 is commonly connected to each gate of the selection transistors at an upper part of the block 1, the selection control line SG12 is commonly connected to each gate of the selection transistors at a lower part, and CG10, CG11, . . . , and CG1n−1 are commonly connected to each gate of the memory cells in the row direction. “CG” has the same meaning as the word line WL, which is a control gate.

TABLE 1

| | Read (connected | | Write (connected | | Erase |
|---|---|---|---|---|---|
| | to CG11) | | to CG11) | | (block 1) |
| BL1 | High (~0.6 V) | | ‘0’:0 V, ‘1’:~1.6 V | | Floating |
| BL2 | High (~0.6 V) | | ‘0’:0 V, ‘1’:~1.6 V | | Floating |
| SL1 | 0~0.2 | V | Same to BL1 | | Floating |
| SL2 | 0~0.2 | V | Same to BL2 | | Floating |
| SG11 | High (~1 V) | | High (~1 V) | | Floating |
| SG12 | High (~1 V) | | High (~1 V) | | Floating |
| CG10 | −0.6~0 | V | High (~5 V) | | 0 V |
| CG11 | ~2 | V | High (8~10 V) | | 0 V |
| CG1n-1 | −0.6~0 | V | High (~5 V) | | 0 V |
| SG21 | 0 | V | 0 | V | Floating |
| SG22 | 0 | V | 0 | V | Floating |
| CG21 | 0 | V | 0 | V | Floating |
| CG22 | 0 | V | 0 | V | Floating |
| CG2n-1 | 0 | V | 0 | V | Floating |
| P well/N well | 0 | V | 0 | V | High (8~14 V) |

It is assumed that the memory cell connected to CG11 of the block 1 is selected. Similar to a two-dimensional NAND flash memory, reading and programming are performed in units of word lines (page unit), and erasing is performed in units of blocks. Table 1 shows voltages applied to each part of the selected block 1 and the non-selected block 2 during reading, programming, and erasing.

[Reading Operation]

In the case of one bit per memory cell, about 2 V is applied to the CG of the selected memory cell, about 0.6 V is applied to the bit line BL, and the source line SL is grounded for reading. About −0.6-0 V is applied to other unselected CGs. A voltage higher than the threshold Vt of the selection transistor is applied to the selection control line SG11 and the selection control line SG12. When the threshold Vt of the memory cell connected to CG11 is lower than VCG11 (“1” cell), the cell current flows from the bit line BL to the source line SL. On the other hand, when the threshold Vt of the memory cell connected to CG11 is higher than VCG11 (“0” cell), the cell current does not flow from the bit line BL to the source line SL. In order to accurately read the data of the memory cell, the threshold Vt of the memory cell must be higher than a CG bias voltage of the non-selected memory cell.

[Programming Operation]

In programming, a high voltage (for example, ˜10 V) is applied to the selected CG11 and an intermediate voltage (for example, ˜5 V) is applied to the non-selected CGs. In the case of “0” programming (electrons are implanted into the charge accumulation layer), 0 V is applied to the bit line BL. The same voltage as that applied to the bit line BL is also applied to the source line SL. In the case of “1” programming (in the case of inhibited programming where electrons are not implanted into the charge accumulation layer), a positive voltage (for example, ˜1.6 V) is applied to the bit line BL. The same voltage as that applied to the bit line BL is also applied to the source line SL.

In “0” programming, the selection control line SG11 and the selection control line SG12 apply a voltage higher than the threshold Vt (for example, ˜1 V) of the selection transistors to turn on the selection transistors, and electrically connect the bit line BL to the diffusion region of the memory cell, and apply 0 V to the diffusion region. Thus, the electrons tunneled from the channel are implanted into the charge accumulation layer 14 of the selected memory cell, and the electrons are accumulated in the charge accumulation layer 14. Since the insufficient intermediate voltage not enough for tunneling through the channel is applied to the gates of the non-selected memory cells, “0” programming is not performed.

In “1” programming, since a positive voltage is applied to the bit line, the selection transistors are turned off by the high voltage of the selection control line SG11 and the selection control line SG12, i.e., the diffusion region of the memory cell becomes a floating state. If a high voltage is applied to CG11, potentials of the diffusion region and the channel are self-boosted due to coupling, and a potential difference between the channel and the charge accumulation layer does not become large enough for tunneling. Therefore, the selected memory cells or the non-selected memory cells are not programmed.

Moreover, 0 V is applied to the selection control line SG21 and the selection control line SG22 of the block 2 to turn off the selection transistors, so that the diffusion regions of the memory cells are separated from the source line SL/bit line BL.

In a certain embodiment, the charge accumulation layer 14 includes at least three insulating layers. The first layer is a lower insulating layer (such as an oxide layer) facing the silicon surface, the second layer is a SiN layer that accumulates charges for data identification, and the third layer is an upper insulating layer (for example, an oxide layer) facing the gate/word line WL. A thickness of effective oxide of the lower insulating layer is thinner than a thickness of effective oxide of the upper insulating layer. The opposite situation is also valid, and in this case, the flow of charges towards the SiN layer during programming is different from that during erasing. In the case that the thickness of the effective oxide film of the lower insulating layer is thin, charges flow between the silicon surface and the SiN layer during programming and erasing. On the other hand, in the case that the thicknesses of the two insulating layers are opposite, the charges flow between SiN and the gate/word line WL during programming and erasing.

As a representative example, the initial example (where the thickness of the lower insulating layer is thinner than the thickness of the upper insulating layer) is described. After the bit line BL is grounded, the memory cell connected to CG11 is subjected to “0” programming (electrons are implanted into SiN from the channel). After a positive voltage (^{˜}1.6 V) is applied to the bit line BL, the two diffusion regions 12 of the source line side and the bit line side are separated from the bit line BL and the source line SL. Therefore, the diffusion region 12 and the channel region apply a high voltage and an intermediate voltage to CG11 and other CGs, thereby enabling self-boosting, a voltage difference between the diffusion region 12 and CG11 becomes smaller, and in the memory cell connected to CG11, electrons are not implanted into the SiN layer from the substrate.

[Erasing Operation]

In the case of erasing, the memory cells of the selected block (selected block 1) are simultaneously erased. The N well and P well formed in the substrate are electrically connected. During the erasing process, a high voltage (such as 8 V˜14 V) is applied to the P well, and all CGs in the selected block are grounded, so that the bit line BL and the source line SL are floating. Then, electrons are tunneled from the SiN layer to the P well, or holes are implanted from the P well into the SiN layer of the memory cell to recombine with the electrons. Thus, the threshold Vt of the memory cell is lower than a read voltage applied to the selected CG during the reading operation. On the other hand, in unselected blocks, all CGs are floating. If a high voltage is applied to the P well, the floating CGs are self-boosted, and the unselected blocks are not erased. In addition, erasing is preferably performed in units of blocks, but may also be performed in units of word lines.

As described above, in the existing AND type flash memory, the charge accumulation layer uses a floating gate (FG). In contrast, in the embodiment, a dielectric (SiN: silicon nitride layer) is used as the charge accumulation layer. In the embodiment, the floating gate is not used, so that the process of manufacturing the memory cells may be simplified.

During programming, the existing AND type flash memories use hot electron implantation to the floating gate, but in the embodiment, electrons tunneling from the channel and diffusion region to the charge accumulation layer by applying a high voltage to the gate are used. In order to avoid obstructing programming of cells that have not been implanted with electrons (“1” programming cells), the diffusion region is in a floating state, and an intermediate voltage is applied to the unselected word line WL, and then both of the channel and the diffusion region are self-boosted, and the voltage difference between the word line WL and the silicon surface is reduced, thereby avoiding implantation of electrons of the “1” programming cell to the charge accumulation layer.

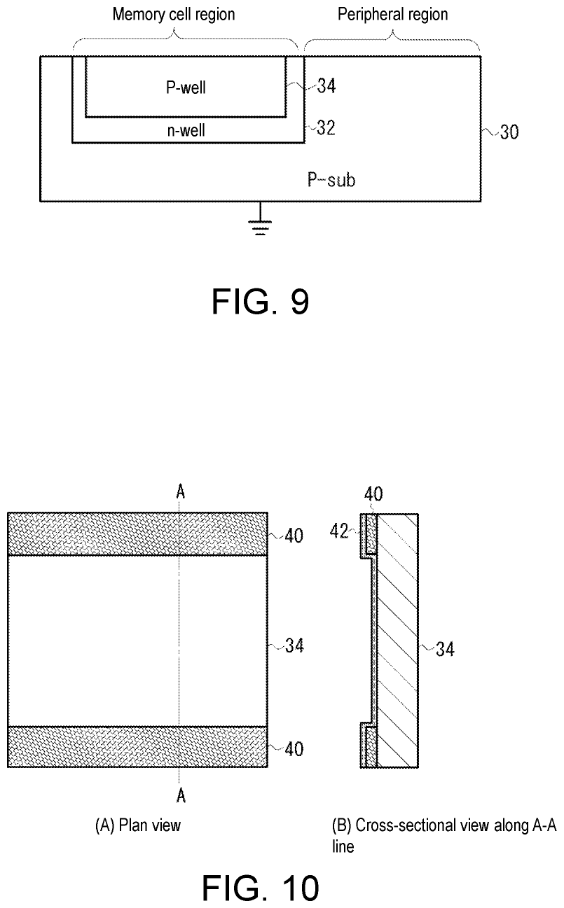

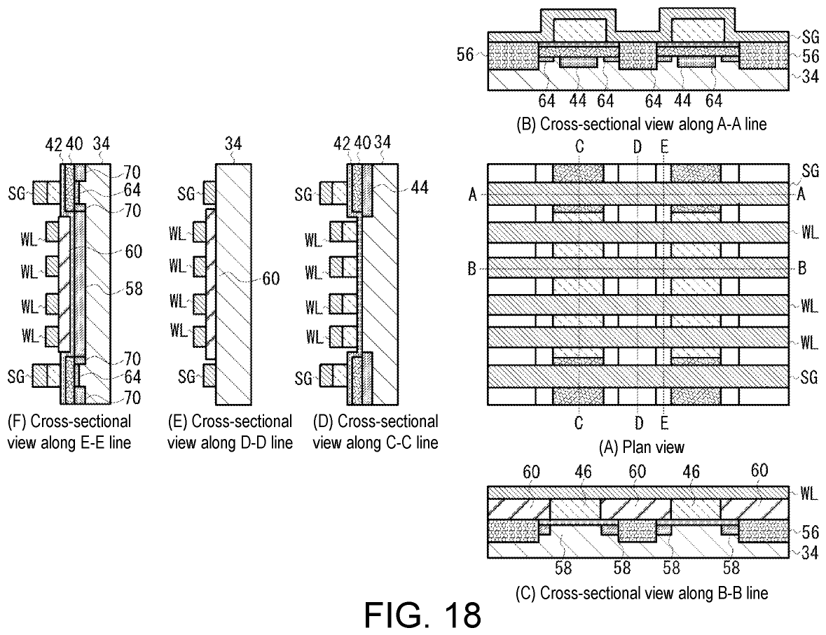

Referring to FIG. 9 to (F) of FIG. 18, a flow for manufacturing the AND type flash memory of an SONOS type of the embodiment is described. As shown in FIG. 2, which shows a process of contacting the bit line BL and the source line SL through both ends of the AND type cell array. However, the flow of a misaligned type of contact shown in FIG. 7 is the same as the flow of the type of contact implemented through both ends.

As shown in FIG. 9, initially an N well 32 is formed in the P-type silicon substrate 30 in the cell array region, and a P well 34 is formed in the N well 32. The P-well 34 provides a region for forming a memory cell. In addition, an N-type silicon substrate may also be used, and in this case, an order of the two wells becomes reversed. The N well 32 is electrically connected to the P well 34, and a high voltage is applied to the two wells 32 and 34 during the erasing operation. As shown in Table 1, during other operations, the two wells 32 and 34 are grounded, and the P-type silicon substrate 30 is always grounded.

After forming the two wells 32 and 34, an insulator 40 for the selection transistors (SSEL1, SSEL2, BSEL1, BSEL2) is formed on the P well 34. Then, as shown in (A) and (B) of FIG. 10, the insulator 40 is patterned so that the insulator remains in the region where the selection transistors are formed. It should also be noted that the insulator 40 is not necessary.

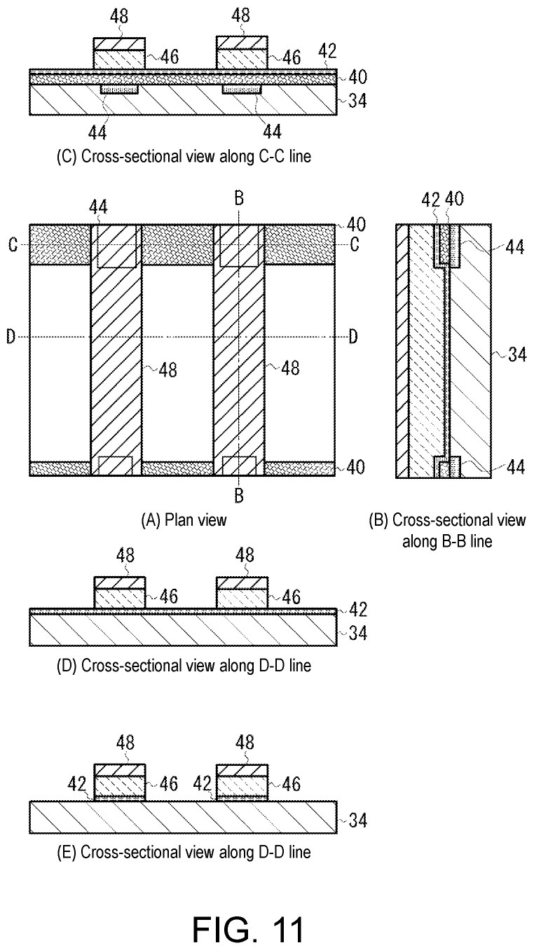

For example, the SiN layer and the charge accumulation layer 42 including the insulating films are deposited on the P-well 34. Then, as shown in (A)-(E) of FIG. 11, boron ion implantation is performed to form a deep P-type diffusion region 44 directly under the insulator 40. As shown in (D) of FIG. 11, a gate material 46 and a mask material 48 are deposited on the charge accumulation layer 42, and patterning is performed in a manner that these materials extend in the column direction. As shown in (E) of FIG. 11, a region of the gate material 46 is etched at the time of patterning, and the charge accumulation layer 42 may also be etched simultaneously. In this way, the charge accumulation layer 42 remains only directly under each gate material 46, and the charge accumulation layer 42 is separated relative to each gate material 46 extending in the column direction.

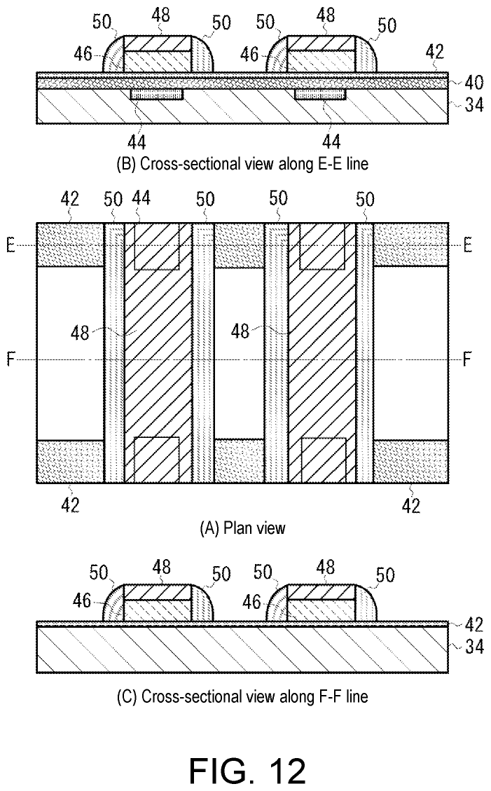

Then, other mask materials (such as silicon oxide film or silicon nitride film, etc., which are not shown) are deposited on the entire surface, and anisotropic etching of the other mask materials is performed, as shown in (A)-(C) of FIG. 12 to form side walls 50 on the gate material 46 and the mask material 48.

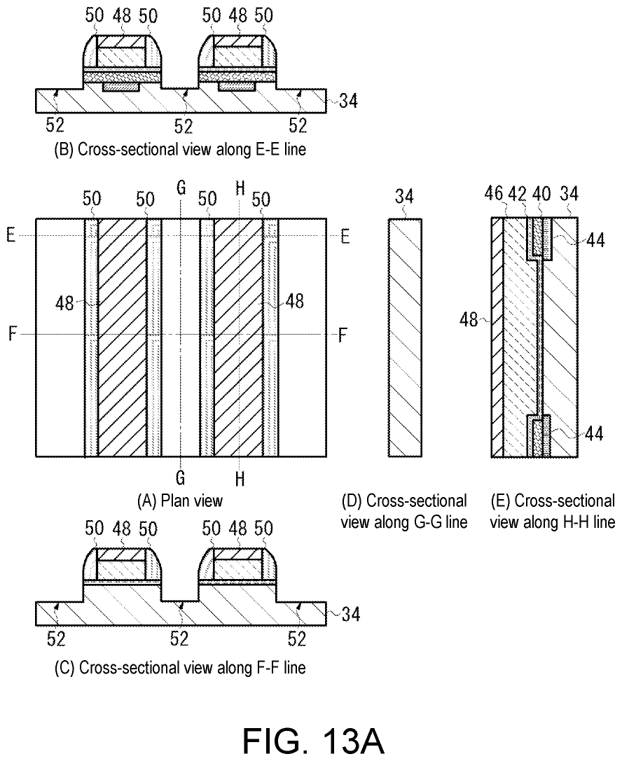

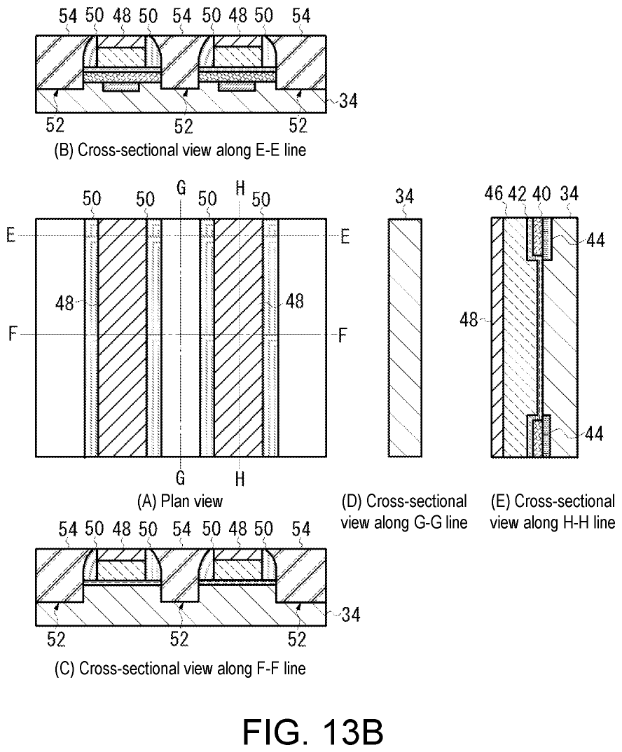

After the side walls 50 are formed, as shown in FIG. 13A, the exposed silicon surface is etched by using the side walls 50 and the mask material 48 on the gate material 46 as an etching mask. Thereafter, trenches 52 formed on the silicon surface are etched to provide shallow trench isolation (STI).

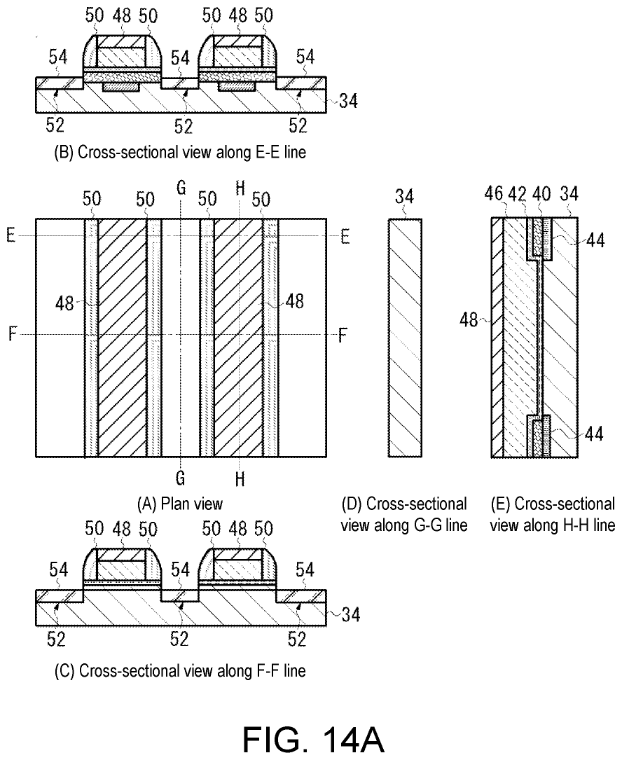

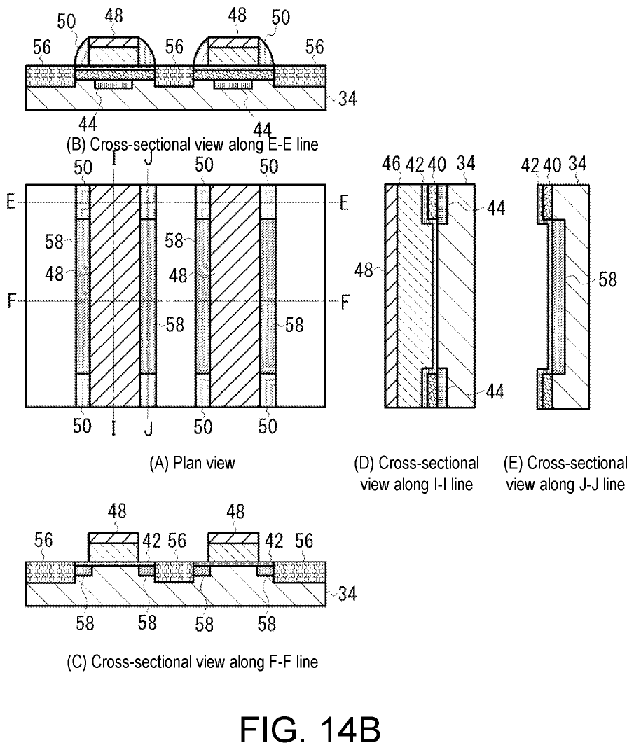

Then, the insulating layer 54 (such as silicon oxide film, etc.) is entirely deposited, and then as shown in FIG. 13B, an upper part of the insulating layer 54 is planarized through chemical mechanical polishing (CMP), etc. Then, as shown in FIG. 14A, the planarized insulating layer 54 is etched back to the vicinity of the charge accumulation layer 42. Then, as shown in FIG. 14B, an insulating region 56 is formed in the trench 52 from, for example, the insulating layer 54 remaining in the trench 52.

Then, as shown in (A) and (C) of FIG. 14B, after removing the side walls 50 of the cell array region except the region where the selection transistors are formed, N-type impurities are implanted to form the diffusion region 58 of the memory cell. As shown in (B) of FIG. 14B, no diffusion region is formed in the region where the selection transistors are formed.

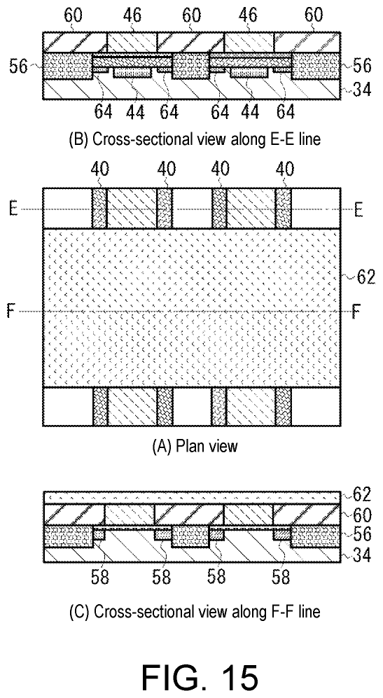

After forming the diffusion region 58, as shown in (A) to (C) of FIG. 15, an interlayer insulation layer 60 is deposited, and the interlayer insulation layer 60 is planarized through CMP to expos the gate material 46. Then, by using a patterned mask 62 as shown in (A) of FIG. 15, the interlayer insulating layer 60 and the side wall 50 are removed by etching in the region of the insulator 40 for the selection transistors.

Then, by using the same mask 62, P-type impurities are implanted into the region of the insulator 40 for the selection transistors to form a high-concentration P-type diffusion region 64. The mask may also be used to adjust the threshold Vt of the selection transistor.

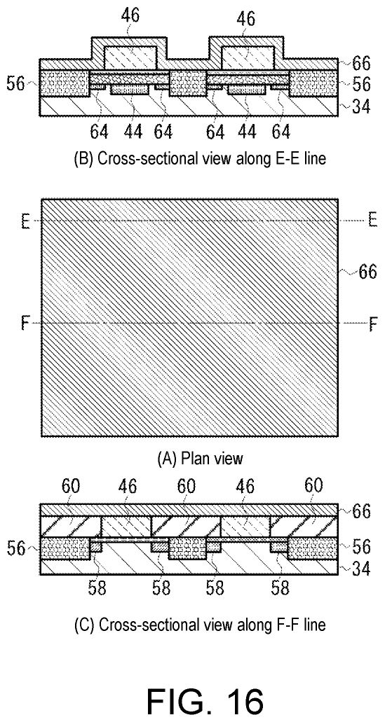

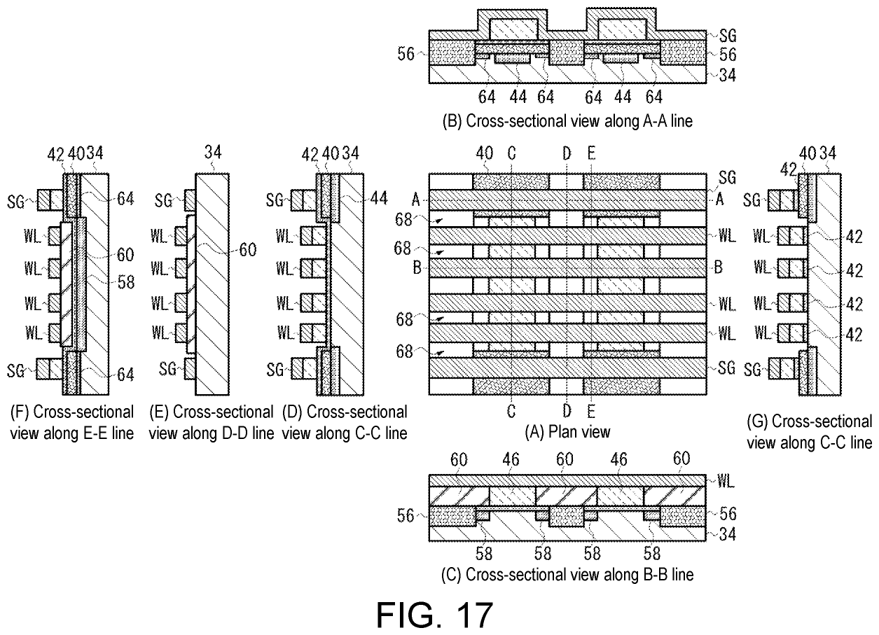

After removing the mask 62, as shown in (A) to (C) of FIG. 16, a second gate material 66 is deposited, and the second gate material 66 is electrically connected to the first gate material 46. After the second gate material 66 is deposited, as shown in (A) of FIG. 17, the first gate material 46 and the second gate material 66 are simultaneously patterned in a manner of extending along the row direction. At this time, as shown in (G) of FIG. 17, the charge accumulation layer 42 may also be patterned simultaneously along with the patterning of the first gate material 46 and the second gate material 66. Namely, the charge accumulation layer 42 remains only directly under the first gate material 46 and the second gate material 66, and in other regions the charge accumulation layer 42 is removed by etching. As a result, the charge accumulation layers 42 in the column direction under the respective WLs and SGs are separated. When the charge accumulation layer 42 remains only under the first gate material 46, the charge accumulation layer 42 is separated from each cell. As a result, charges accumulated in each cell by programming and erasing cannot diffuse to adjacent cells, which further improves data retention.

Then, as shown in (A) to (G) of FIG. 17, the word line WL/selection control line SG and a space 68 in the row direction thereof are formed. After the gate is patterned, as shown in (A) to (F) of FIG. 18, heavily doped N-type impurities are implanted into a region 70 of the insulator 40 of the selection transistor. The region 70 provides the source/drain of the selection transistor.

Then, an interlayer insulating layer is deposited, and a contact hole is formed through the interlayer insulating layer. Finally, as shown in FIGS. 5-7, a metal material is deposited, and the metal material is patterned to form bit lines BL and source lines SL extending along the column direction. The bit lines BL and the source lines SL are electrically connected to the heavily doped N-type diffusion region 70.

As another example of fabricating the AND type flash memory of the SONOS type, the timing of forming the diffusion region 58 that provides the source/drain of the memory cell may be changed. Namely, the N-type impurities may be implanted just after patterning the first gate material 46 which may be used as a mask for ion implantation. Furthermore, as shown in FIG. 14A, FIG. 14B and (A) to (C) of FIG. 15, before implanting the P-type impurities, as in FIG. 14A, FIG. 14B and (A) to (C) of FIG. 15, the region of the selection transistors is masked with photoresist.

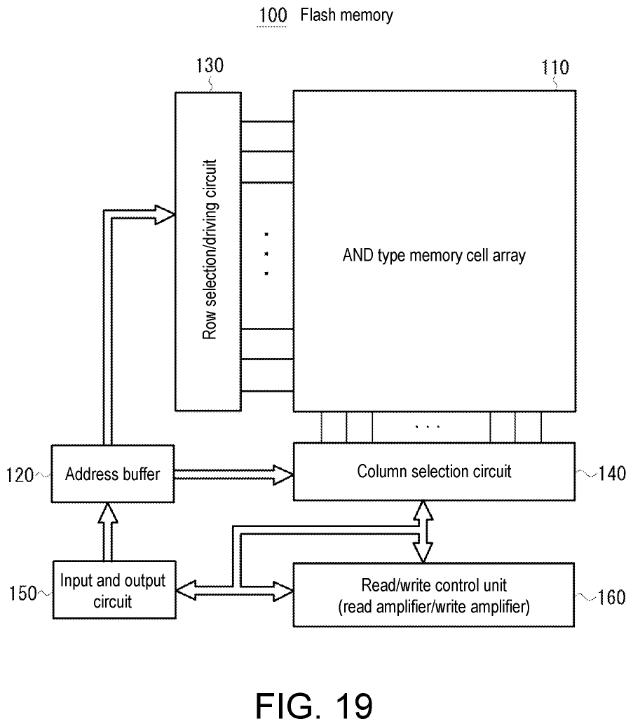

FIG. 19 is a block diagram showing a main electrical structure of an AND type flash memory of the embodiment. A flash memory 100 includes: a memory cell array 110, which has an AND type memory cell array structure; an address buffer 120, which maintains addresses input from the outside; a row selection/driving circuit 130, which selects a word line etc., based on a row address, and drives the selected word line etc.; a column selection circuit 140, which selects a bit line or a source line etc., based on a column address; an input and output circuit 150, which transceives data or instructions with an external host device, etc.; a read/write control unit 160, which reads data read from the selected memory cell during the reading operation, or applies a bias voltage for writing the selected memory cell to the bit line during the programming operation, or applies an erase voltage to the P well, etc., during the erasing operation. Each part is connected by an internal bus capable of transmitting and receiving addresses, data, control signals, etc., and, although not shown here, a voltage generation circuit for generating various bias voltages is included.

The row selection/driving circuit 130 selects the word line WL based on a row address, and drives the selected word line WL and the non-selected word line with a voltage corresponding to the operation. The row selection/driving circuit 130 applies the voltages shown in Table 1 to the word line WL (CG) and the selection control line (SG).

The column selection circuit 140 selects the bit line BL and the source line SL based on a column address, and applies a voltage corresponding to the operation to the selected bit line BL and the source line SL, or sets the same in a floating state.

The read/write control unit 160 controls reading, programming, and erasing operations according to commands received from an external host device. The read/write control unit 160 includes a read amplifier or a write amplifier, etc. The read amplifier reads a current or voltage flowing in the bit line BL and source line SL connected to the selected memory cell during the reading operation. The write amplifier applies a read voltage to the selected bit line during the reading operation, or applies a voltage to the selected bit line or non-selected bit line during the programming operation, thereby setting the bit line or source line to the floating state during the erasing operation.

Preferred embodiments of the invention have been described in detail, but the invention is not limited to the specific embodiments, and various modifications and changes may be made within the scope of the spirit of the invention described in the claims.

What is claimed is:

1. An AND type flash memory, comprising a memory cell array, wherein the memory cell array comprises a plurality of memory cells electrically connected in parallel between a source line and a bit line,
a plurality of parallel and elongated diffusion regions are formed in the memory cell array,
the plurality of memory cells connected in parallel respectively comprise a gate and a charge accumulation layer, the gate is disposed between the diffusion regions opposite to each other, the charge accumulation layer serves as a gate insulating film, and is capable of storing charges, and the charge accumulation layer comprises at least three or more insulating layers.

2. The AND type flash memory as claimed in claim 1, wherein the charge accumulation layer comprises a nitride layer for storing charges.

3. The AND type flash memory as claimed in claim 2, wherein the charge accumulation layer comprises the nitride layer between an upper insulating layer and a lower insulating layer.

4. The AND type flash memory as claimed in claim 1, wherein the charge accumulation layer is separated relative to each memory cell in a column direction or a row direction.

5. The AND type flash memory as claimed in claim 1, wherein the charge accumulation layer is separated relative to each memory cell.

6. The AND type flash memory as claimed in claim 1, wherein the charge accumulation layer accumulates charges tunneled from a channel when a program voltage is applied to the gate of the selected memory cell.

7. The AND type flash memory as claimed in claim 1, wherein when a reference voltage is applied to the gate of the selected memory cell and an erase voltage is applied to a well region, the charge accumulation layer releases the accumulated charges to a channel through tunneling, or recombine accumulated electrons with holes tunneled from the channel.

8. The AND type flash memory as claimed in claim 1, wherein the memory cell array further comprises a selection transistor of a source line side and a selection transistor of a bit line side, the selection transistor of the source line side is configured to selectively connect one of the diffusion regions common to a block of n memory cells connected in parallel to the source line, and the selection transistor of the bit line side is configured to selectively connect the other diffusion region common to the block to the bit line,
when the selection transistor of the source line side is turned on, one of the diffusion regions of the block is electrically connected to the source line, and when the selection transistor of the bit line side is turned on, the other diffusion region of the block is electrically connected to the bit line.

9. The AND type flash memory as claimed in claim 8, wherein the selection transistor of the source line side comprises a first selection transistor and a second selection transistor, the first selection transistor is configured to connect one of the diffusion regions of the first memory cell of the block to the source line, and the second selection transistor is configured to connect one of the diffusion regions of the last memory cell to the source line,
the selection transistor of the bit line side comprises a first selection transistor and a second selection transistor, and the first selection transistor is configured to connect the other diffusion region of the first memory cell of the block to the bit line, and the second selection transistor is configured to connect the other diffusion region of the last memory cell to the bit line,
the gates of the first transistor of the source line side and the first transistor of the bit line side are commonly connected to a corresponding first selection control line,
the gates of the second transistor of the source line side and the second transistor of the bit line side are commonly connected to a corresponding second selection control line.

10. The AND type flash memory as claimed in claim 9, wherein each gate of the n memory cells in the block is respectively connected to a word line extending along a row direction on the memory cell array, the first selection control line and the second selection control line extend parallel to the word line.

11. The AND type flash memory as claimed in claim 8, wherein one of the diffusion regions of the selection transistor of the source line side is electrically connected to one of the diffusion regions of the memory cell, and the other diffusion region is electrically connected to the source line through a conductive contact member,
one of the diffusion regions of the selection transistor of the bit line side is in common with the other diffusion region of the memory cell, and the other diffusion region is electrically connected to the bit line through a conductive contact member.

12. The AND type flash memory as claimed in claim 11, wherein the selection transistor of the source line side comprises stacked layers of a charge accumulation layer serving as a gate insulating film and other insulating films, and the selection transistor of the bit line side comprises stacked layers of a charge accumulation layer serving as a gate insulating film and other insulating films.

13. The AND type flash memory as claimed in claim 8, further comprising a programming control part, wherein the programming control part controls programming of the memory cells,
in the case that the programming control part prohibits programming of the selected memory cell, a first selection transistor and a second selection transistor are turned off, so that one of the diffusion regions and the other diffusion region of the block are floating, and a program voltage is applied to a selected word line, and an intermediate voltage is applied to non-selected word lines.

14. The AND type flash memory as claimed in claim 13, wherein when the programming control part programs the selected memory cell, the first selection transistor and the second selection transistor are turned on, so that one of the diffusion regions and the other diffusion region of the block are electrically connected to the source line and the bit line, a program voltage is applied to the selected word line and an intermediate voltage is applied to the non-selected word lines.

15. The AND type flash memory as claimed in claim 8, further comprising an erasing control part, wherein the erasing control part controls erasing of the memory cells,
in the case that the erasing control part erases the memory cells of the block all at once, a reference voltage is applied to the gates of the memory cells of the block, so that a first selection transistor and a second selection transistor are floating, and an erase voltage is applied to a well region comprising the channel.

16. A programming method, adapted to an AND type flash memory, wherein the AND type flash memory comprises a memory cell array, the memory cell array comprises a plurality of memory cells electrically connected in parallel between a source line and a bit line, wherein
a plurality of parallel and elongated diffusion regions are formed in the memory cell array,
the plurality of memory cells connected in parallel respectively comprise a gate and a charge accumulation layer, the gate is disposed between the diffusion regions opposite to each other, the charge accumulation layer serves as a gate insulating film, and comprises at least three or more insulating layers,
a program voltage is applied to the gate of a selected memory cell, and a reference voltage is applied to a channel, thereby accumulating charges tunneled from the channel in the charge accumulation layer.

17. The programming method as claimed in claim 16, wherein the common diffusion region of the selected memory cell and a non-selected memory cell connected in parallel is set to a floating state, by applying a voltage to each gate of the selected memory cell and the non-selected memory cell, the diffusion regions of the selected memory cell and the channel are self-boosted, thereby prohibiting programming of the selected memory cell.

18. The programming method as claimed in claim 16, wherein a reference voltage is applied to a common diffusion region of the selected memory cell and the non-selected memory cell connected in parallel, a program voltage is applied to the gate of the selected memory cell, and an intermediate voltage is applied to the non-selected memory cell, thereby performing programming of the selected memory cell.

19. An erasing method, adapted to an AND type flash memory, wherein the AND type flash memory comprises a memory cell array, the memory cell array comprises a plurality of memory cells electrically connected in parallel between a source line and a bit line, wherein
a plurality of parallel and elongated diffusion regions are formed in the memory cell array,
the plurality of memory cells connected in parallel respectively comprise a gate and a charge accumulation layer, the gate is disposed between the diffusion regions opposite to each other, and the charge accumulation layer serves as a gate insulating film, and comprises at least three or more insulating layers,
a reference voltage is applied to the gate of a selected memory cell, and an erase voltage is applied to a well comprising a channel, and charges accumulated in the charge accumulation layer are released to the channel through tunneling.

20. The erasing method as claimed in claim 19, wherein a block comprising a plurality of memory cells connected in parallel is selected, and the plurality of memory cells in the selected block are erased all at once.
